(19) United States
(12) Patent Application Publication
(10) Pub. No.: US 2009/0058483 A1
(43) Pub. Date: Mar. 5, 2009

(54) DUTY CYCLE CORRECTING CIRCUIT AND METHOD

(75) Inventors: Dong-Suk Shin, Ichon (KR); Hyun-Woo Lee, Ichon (KR); Won-Joo Yun, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/200,747

(22) Filed: Aug. 28, 2008

(30) Foreign Application Priority Data
Sep. 4, 2007 (KR) 10-2007-0089487

(51) Int. Cl. H03K 3/017

(52) U.S. Cl. 327/175

(57) ABSTRACT

A duty cycle correcting circuit includes a duty detector that detects a duty ratio of an output clock signal to output a duty detection signal, a variable delay unit that outputs a delay clock signal obtained by variably delaying a input signal according to the duty detection signal, and a pulse width modulating unit that generates a first clock signal that is at a high level when both the input clock signal and the delay clock signal are at a high level and generates a second clock signal that is at a high level when any of the input clock signal and the delay clock signal is at a high level, wherein the pulse width modulating unit selectively outputs the first clock signal or the second clock signal as the output clock signal.

### CROSS-REFERENCES TO RELATED APPLICATION

The present application claims priority under 35 U.S.C. §119(a) to Korean Patent Application No. 10-2007-0089487, filed in the Korean Intellectual Property Office on Sep. 4, 2007, which is incorporated by reference in its entirety as if set forth in full.

### BACKGROUND

1. Technical Field

The embodiments described herein relate to a semiconductor integrated circuit (IC) and more specifically to a duty cycle correcting circuit and a method of correcting a duty cycle.

2. Related Art

Generally, a duty cycle correcting circuit performs an operation that generates a specified ratio of a high-level interval to a low-level interval of a clock period, i.e., a conventional duty cycle correcting circuit controls the duty ratio of clock signal. Often, a duty cycle correcting circuit makes the high-level interval substantially equal to the low-level interval for the clock signal being controlled.

A conventional duty cycle correcting circuit 10, as shown in FIG. 1 (for example, see U.S. Patent Application Publication No. US20050007168), includes a clock generation block 11, having a clock rising edge generation block 12 and a clock falling edge generation block 13, a clock delay block 14, and a digital duty cycle detection circuit 17. Here, the clock delay block 14 delays a clock signal. The clock delay block 14, the clock rising edge generation block 12 and the clock falling edge generation block 13 include a plurality of inverters that are connected in series with each other respectively. If the frequency of a clock signal received by the clock delay block 14, the clock rising edge generation block 12 and the clock falling edge generation block 13 increases, the clock delay block 14, the clock rising edge generation block 12 and the clock falling edge generation block 13 may consume more power and cause jitter components. i.e., time-domain distortion, within the clock signal. Accordingly, in a conventional duty cycle correcting circuit, as the frequency of a clock signal increases, power consumption may increase and more jitter components may be added to an output clock signal.

### SUMMARY OF THE INVENTION

A duty cycle correcting circuit and method of correcting a duty cycle that uses less power consumption and prevents jitter components from occurring in a clock signal are described herein.

In one aspect, a duty cycle correcting circuit includes a duty detector that detects a duty ratio of an output clock signal to output a duty detection signal, a variable delay unit that outputs a delay clock signal obtained by variably delaying a input signal according to the duty detection signal, and a pulse width modulating unit that generates a first clock signal that is at a high level when both the input clock signal and the delay clock signal are at a high level and generates a second clock signal that is at a high level when any of the input clock signal and the delay clock signal is at a high level, wherein the pulse width modulating unit selectively outputs the first clock signal or the second clock signal as the output clock signal.

In another aspect, a method for correcting a duty cycle of a clock signal includes detecting a duty ratio of an output clock signal to output a duty detection signal, outputting a delay clock signal that is obtained by variably delaying a input signal according to the duty detection signal, and correcting the duty ratio of the output clock signal by increasing or decreasing a width of a high-level pulse of the output clock signal as much as a delay time by which the delay clock signal is delayed according to the duty ratio of the output clock signal.

In another aspect, a duty cycle correcting circuit includes a duty detector that outputs a duty detection signal based upon a duty ratio of an output clock signal, a variable delay unit that outputs a delay clock signal based upon the duty detection signal and a input clock signal, and outputs a control signal based upon the duty detection signal, a first pulse generating unit that outputs a first clock signal based upon the delay clock signal, a second pulse generating unit that outputs a second clock signal based upon the delay clock signal, and a selection output unit that outputs the output clock signal based upon the first clock signal, the second clock signal, and the control signal.

These and other features, aspects, and embodiments are described below.

### BRIEF DESCRIPTION OF THE DRAWINGS

Features, aspects, and embodiments are described in conjunction with the attached drawings, in which:

FIG. 1 is a schematic circuit diagram of a conventional duty cycle correcting circuit;

FIG. 2 is a schematic circuit diagram of an exemplary duty cycle correcting circuit according to one embodiment;

FIG. 3 is a schematic circuit diagram of an exemplary pulse width modulating unit of the duty cycle correcting circuit of FIG. 2 according to one embodiment;

FIG. 4 is an exemplary timing diagram of the duty cycle correcting circuit of FIG. 2 according to one embodiment;

FIG. 5A is a schematic circuit diagram of an exemplary NAND gate applicable to the pulse width modulating unit of FIG. 3 according to one embodiment;

FIG. 5B is a schematic circuit diagram of an exemplary NOR gate applicable to the pulse width modulating unit shown of FIG. 3 according to one embodiment;

FIG. 6 is a schematic circuit diagram of an exemplary duty detector shown of FIG. 2 according to one embodiment; and

FIG. 7 is a schematic circuit diagram of an exemplary variable delay unit shown of FIG. 2 according to one embodiment.

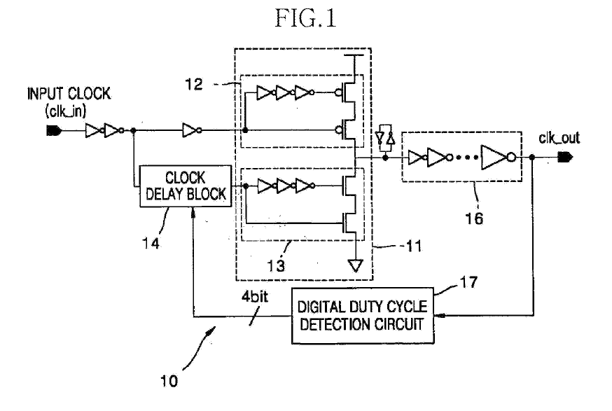

### DETAILED DESCRIPTION

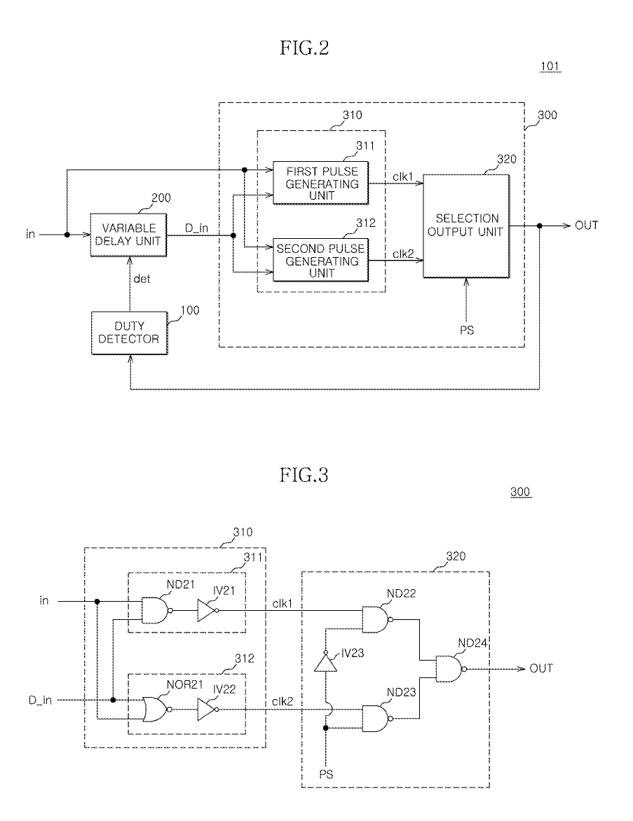

FIG. 2 is a schematic circuit diagram of an exemplary duty cycle correcting circuit 101 according to one embodiment. Referring to FIG. 2, the duty cycle correcting circuit 101includes a duty detector 100, a variable delay unit 200, and a pulse width modulating unit 300.

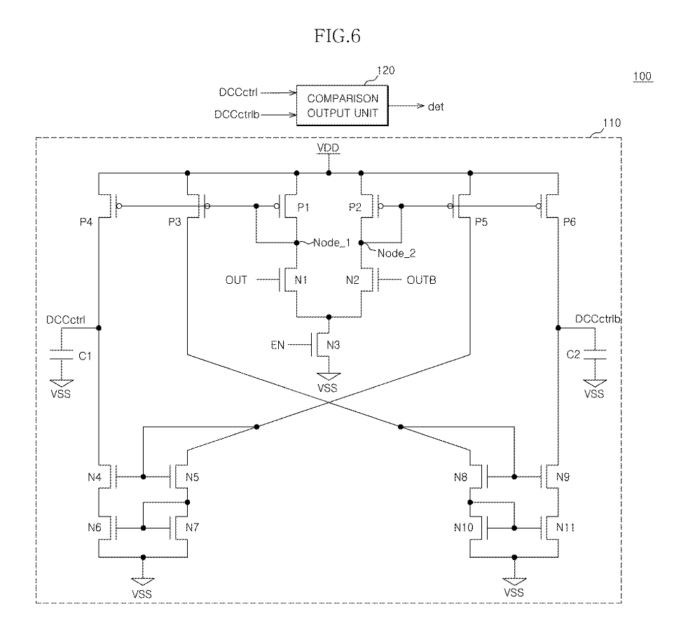

The duty detector 100 can be configured to detect a duty ratio of an output clock signal ‘OUT’ to generate a duty detection signal ‘det’. The duty detector 100 can further be configured to compare the high level interval of the output clock signal ‘OUT’ with the low-level interval of the output clock signal ‘OUT’ and generate the duty detection signal ‘det’. The duty detector 100 can include a duty comparing unit 110 and a comparison output unit 120, as shown in FIG. 6.

The duty comparing unit 110 can be configured to receive the output clock signal ‘OUT’ and the inverted signal of the output clock signal ‘OUTB’, and compare the high-level interval of the two signals to generate a first comparison voltage DCCctrl and a second comparison voltage DCCctrlb. For instance, if the high level interval of the output clock signal ‘OUT’ is greater than the high level interval the inverted signal ‘OUTB’ then the duty comparing unit 110 can generate the first comparison voltage DCCctrl and the second comparison voltage DCCctrlb so that the first comparison voltage DCCctrl has a level greater than a level of the second comparison voltage DCCctrlb. On the contrary, if the high level interval of the output clock signal ‘OUT’ is less than the high level interval of the inverted signal ‘OUTB’, then the duty comparing unit 110 can generate the first comparison voltage DCCctrl and the second comparison voltage DCCctrlb so that the first comparison voltage DCCctrl has a lower level than that of the second comparison voltage DCCctrlb.

In the duty comparing unit 110, the voltage at a first node (Node_1) and the voltage at a second node (Node_2) vary with the voltage levels of the output clock signal ‘OUT’ and the inverted signal ‘OUTB’. Voltages are charged to a first capacitor C1 and a second capacitor C2 according to the voltage levels at the first node (Node_1) and the second node (Node_2). The voltage charged to the first capacitor C1 is output as the first comparison voltage DCCctrl, and the voltage charged to the second capacitor C2 is output as the second comparison voltage DCCctrlb.

The duty comparing unit 110 can include first to eleventh NMOS transistors N1 to N11, first to sixth PMOS transistors P1 to P6, and first and second capacitors C1 and C2, as shown in FIG. 6. The first NMOS transistor N1 can receive the output clock signal ‘OUT’ through its gate terminal. The second NMOS transistor N2 can receive the inverted signal ‘OUTB’ through its gate terminal. The third NMOS transistor N3 can receive an enable signal ‘EN’ through its gate terminal. The drain terminal of the third NMOS transistor N3 can be connected to the source terminal of the first and second NMOS transistors N1 and N2, and the source terminal of the third NMOS transistor N3 can be connected to a ground terminal VSS. The gate terminal and drain terminal of the first PMOS transistor P1 can be connected to the drain terminal of the first NMOS transistor N1.

The first PMOS transistor P1 can receive an external voltage VDD through its source terminal. The gate terminal and drain terminal of the second PMOS transistor P2 can be connected to the drain terminal of the second NMOS transistor N2. The second PMOS transistor P2 can receive the external voltage VDD through its source terminal. The gate terminal of the third PMOS transistor P3 can be connected to the drain terminal of the first NMOS transistor N1. The third PMOS transistor P3 can receive the external voltage VDD through its source terminal. The gate terminal of the fourth PMOS transistor P4 can be connected to the drain terminal of the first NMOS transistor N1. The fourth PMOS transistor P4 can receive the external voltage VDD through its source terminal. The gate terminal of the fifth PMOS transistor P5 is connected to the drain terminal of the second NMOS transistor N2. The fifth PMOS transistor P5 can receive the external voltage VDD through its source terminal. The gate terminal of the sixth PMOS transistor P6 can be connected to the drain terminal of the second NMOS transistor N2. The sixth PMOS transistor P6 can receive the external voltage VDD through its source terminal.

The drain terminal of the fourth NMOS transistor N4 can be connected to the drain terminal of the fourth PMOS transistor P4, and the gate terminal of the fourth NMOS transistor N4 can be connected to the drain terminal of the fifth PMOS transistor P5. The gate terminal and the drain terminal of the fifth NMOS transistor N5 can be connected to the drain terminal of the fifth PMOS transistor P5. The drain terminal of the sixth NMOS transistor N6 can be connected to the source terminal of the fourth NMOS transistor N4, the gate terminal of the sixth NMOS transistor N6 can be connected to the source terminal of the fifth NMOS transistor N5, and the source terminal of the sixth NMOS transistor N6 can be connected to a ground terminal VSS.

The gate terminal and the drain terminal of the seventh NMOS transistor N7 can be connected to the source terminal of the fifth NMOS transistor N5, and the source terminal of the seventh NMOS transistor N7 can be connected to the ground terminal VSS. The gate terminal and the drain terminal of the eighth NMOS transistor N8 can be connected to the drain terminal of the third PMOS transistor P3. The drain terminal of the ninth NMOS transistor N9 can be connected to the drain terminal of the sixth PMOS transistor P6, and the gate terminal of the ninth NMOS transistor N9 can be connected to the drain terminal of the third PMOS transistor P3. The gate terminal and the drain terminal of the tenth NMOS transistor N10 can be connected to the source terminal of the eighth NMOS transistor N8, and the source terminal of the tenth NMOS transistor N10 can be connected to a ground terminal VSS. The gate terminal of the eleventh NMOS transistor N11 can be connected to the source terminal of the eighth NMOS transistor N8, the drain terminal of the eleventh NMOS transistor N11 can be connected to the source terminal of the ninth NMOS transistor N9, and the source terminal of the eleventh NMOS transistor N11 can be connected to the ground terminal VSS.

One terminal of the first capacitor C1 can be connected to a node to which the drain terminal of the fourth PMOS transistor P4 and the drain terminal of the fourth NMOS transistor N4 are connected, and the other terminal of the first capacitor C1 can be connected to a ground terminal VSS. One terminal of the second capacitor C2 can be connected to a node to which the drain terminal of the sixth PMOS transistor P6 and the drain terminal of the ninth NMOS transistor N9 are connected, and the other terminal of the second capacitor C2 can be connected to a ground terminal VSS.

In this case, the voltage difference between the two terminals of the first capacitor C1 corresponds to the first comparison voltage DCCctrl and the voltage difference between the two terminals of the second capacitor C2 corresponds to the second comparison voltage DCCctrlb. Further, the first node (Node_1) can correspond to a node to which the drain terminal of the first PMOS transistor P1 and the drain terminal of the first NMOS transistor N1 are connected, and the second node (Node_2) can correspond to a node to which the drain terminal of the second PMOS transistor P2 and the drain terminal of the second NMOS transistor N2 are connected.

The comparison output unit 120 can be configured to compare the level of the first comparison voltage DCCctrl with the level of the second comparison voltage DCCctrlb to generate the duty detection signal ‘det’. For example, if the first comparison voltage DCCctrl has a level greater than a level of the second comparison voltage DCCctrlb, then the comparison output unit 120 can enable the duty detection signal ‘det’. On the contrary, if the first comparison voltage DCCctrl has a level lower than a level of the second comparison voltage DCCctrlb, then the comparison output unit 120 can disable the duty detection signal ‘det’. As an example, the comparison output unit 120 can be implemented as a common comparator.

The variable delay unit 200 delays an input clock signal ‘in’ to generate a delayed clock signal ‘D_in’ in response to the duty detection signal ‘det’. The duty detection signal ‘det’ is enabled, then the variable delay unit 200 can be configured to increase a delay time. If the duty detection signal ‘det’ is disabled, then the variable delay unit 200 can be configured to decrease the delay time.

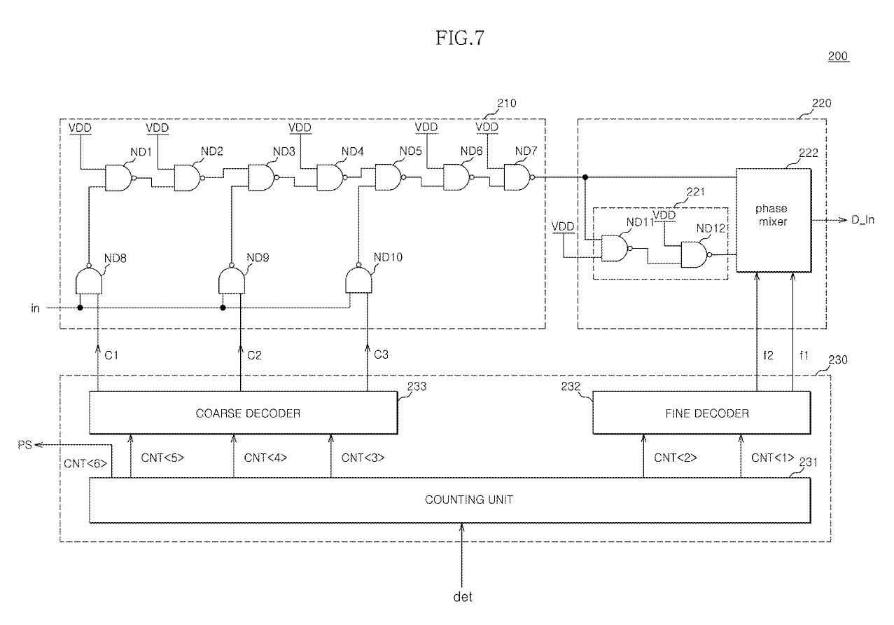

Referring to FIG. 7, the variable delay unit 200 can include a coarse delay line 210, a fine delay line 220, and a delay control unit 230. The delay control unit 230 can be configured to generate first to third coarse control signals ‘C1’, ‘C2’, and ‘C3,’ first and second fine control signals ‘f1’ and ‘f2,’ and a selection control signal ‘PS’ in response to the duty detection signal ‘det.’

The delay control unit 230 can include a counting unit 231, a fine decoder 232, and a coarse decoder 233. The counting unit 231 can be configured to up-count counter values ‘CNT<1>’ to ‘CNT<6>’ if the duty detection signal ‘det’ is enabled and down-count the counter values ‘CNT<1>’ to ‘CNT<6>’ if the duty detection signal ‘det’ is disabled. In certain embodiments, out of the counter values ‘CNT<1>’ to ‘CNT<6>’, the most significant bit CNT<6> is output as the selection control signal ‘PS’. In addition, each of the counter values ‘CNT<1>’ to ‘CNT<6>’ can have an initial value. For example, the counter values ‘CNT<1>’, ‘CNT<2>’, ‘CNT<3>’, ‘CNT<4>’, ‘CNT<5>’, and ‘CNT<6>’ can have initial values 0, 0, 0, 0, 0, and 1, respectively, or 1, 1, 1, 1, 1, and 0, respectively.

The fine decoder 232 can be configured to decode the lower-order bits ‘CNT<1>’ and ‘CNT<2>’ out of the counter values ‘CNT<1>’ to ‘CNT<6>’ to generate the first and second fine control signals ‘f1’ and ‘f2’. For example, if the lower-order bits ‘CNT<1>’ and ‘CNT<2>’ are 1 and 0, respectively, then the fine decoder 232 can enable the first fine control signal ‘f1’. If, on the other hand, the lower-order bits ‘CNT<1>’ and ‘CNT<2>’ are 1 and 1, respectively, then the fine decoder 232 can enable the second fine control signal ‘f2’.

The course decoder 233 can be configured to decode three intermediate bits ‘CNT<3>’ to ‘CNT<5>’ to generate the first to third coarse control signals ‘C1’, ‘C2’, and ‘C3’. For example, if the intermediate bits ‘CNT<3>’ to ‘CNT<5>’ are 1, 0, and 0, respectively, then the coarse decoder 233 can enable the first coarse control signal ‘C1’. If the intermediate bits ‘CNT<3>’ to ‘CNT<5>’ are 0, 0, and 1, respectively, then the coarse decoder 233 can enable the second coarse control signal ‘C2’. If the intermediate bits ‘CNT<3>’ to ‘CNT<5>’ are 1, 1, and 1, respectively, then the coarse decoder 233 can enable the third coarse control signal ‘C3’.

In the coarse delay line 210, the delay time varies depending on the first to third coarse control signals ‘C1’, ‘C2’, and ‘C3’. For instance, if the first coarse control signal ‘C1’ is enabled, then the delay time is minimized. If the second coarse control signal ‘C2’ is enabled, then the delay time becomes longer than the delay time when the first coarse control signal ‘C1’ is enabled. If the third coarse control signal ‘C3’ is enabled, then the delay time is maximized. As a consequence, the coarse delay line 210 can delay the input clock signal ‘in’ by a delay time set according to the first to third coarse control signals ‘C1’, ‘C2’, and ‘C3’, and output the delayed input clock to the fine delay line 220.

The coarse delay line 210 can include first to tenth NAND gates ND1 to ND10. The first NAND gate ND1 can receive an external voltage VDD through a first input terminal and receive an output signal from the eighth NAND gate ND8 through a second input terminal. The second NAND gate ND2 can receive an external voltage VDD through a first input terminal and receive an output signal from the first NAND gate ND1 through a second input terminal. The third NAND gate ND3 can receive an output signal from the second NAND gate ND2 through a first input terminal and receive an output signal from the ninth NAND gate ND9 through a second input terminal. The fourth NAND gate ND4 can receive an external voltage VDD through a first input terminal and receive an output signal from the third NAND gate ND3 through a second input terminal. The fifth NAND gate ND5 can receive an output signal from the fourth NAND gate ND4 through a first input terminal and receive an output signal from the tenth NAND gate ND10 through a second input terminal. The sixth NAND gate ND6 can receive an external voltage VDD through a first input terminal and receive an output signal from the fifth NAND gate ND5 through a second input terminal. The seventh NAND gate ND7 can receive an external voltage VDD through a first input terminal and receive an output signal from the sixth NAND gate ND6 through a second input terminal. The eighth NAND gate ND8 can receive the input clock signal ‘in’ through a first input terminal and receives the first coarse control signal ‘C1’ through a second input terminal. The ninth NAND gate ND9 can receive the input clock signal ‘in’ through a first input terminal and receives the second coarse control signal ‘C2’ through a second input terminal. The tenth NAND gate ND10 can receive the input clock signal ‘in’ through a first input terminal and receive the third coarse control signal ‘C3’ through a second input terminal.

Thus, in this embodiment, the output terminal of the seventh NAND gate ND7 corresponds to the output terminal of the coarse delay line 210. The coarse delay line 210, as configured above, delays the input clock signal ‘in’ by the delay time according to the first to third coarse control signals ‘C1’, ‘C2’, and ‘C3’, and outputs the delayed input clock to the fine delay line 220.

The fine delay line 220 can include a delay unit 221 and a phase mixer 222. The delay unit 221 can receive the signal output from the coarse delay line 210. The delay line 221 can include an eleventh NAND gate ND11 and a twelfth NAND gate ND12. The eleventh NAND gate ND11 can receive the signal output from the coarse delay line 210 through a first input terminal and receive an external voltage VDD through a second input terminal. The twelfth NAND gate ND12 can receive an external voltage VDD through a first input terminal and receive an output signal from the eleventh NAND gate ND11 through a second input terminal. The output signal from the twelfth NAND gate ND12 is output to the phase mixer 222.

The phase mixer 222 can be controlled by the first and second fine control signals ‘f1’ and ‘f2’ so that the delay clock signal ‘D_in’ has a phase between the phase of the signal output from the coarse delay line 210 and the phase of the signal output from the delay unit 221. For example, if the first fine control signal ‘f1’ is enabled, then the phase mixer 222 can output the delay clock signal ‘D_in’ whose phase is closer to the phase of the signal output from the coarse delay line 210 than the phase of the signal output from the delay unit 221. If the second fine control signal ‘f2’ is enabled, then the phase mixer 222 can output the delay clock signal ‘D_in’ whose phase is closer to the phase of the signal output from the delay line 221 than the phase of the signal output from the coarse delay line 210.

Referring again to FIG. 2, the pulse width modulating unit 300 can be configured to generate a first clock signal ‘clk1’. The high-level interval of the first clock signal ‘clk1-’ can correspond to the period during which the high-level interval of the input clock signal ‘in’ and the high-level interval of the delay clock signal ‘D_in’ overlap. The pulse width modulating unit 300 can also be configured to generate a second clock signal ‘clk2’ the high level interval of which corresponds to the high-level interval of either the input clock signal ‘in’ and or the delay clock signal ‘D_in’. The pulse width modulating unit 300 can then be configured to selectively output the first clock signal ‘clk1’ or the second clock signal ‘clk2’ as the output clock signal ‘OUT’ in response to the control signal ‘PS’.

The pulse width modulating unit 300 can include a pulse variable unit 310 and a selection output unit 320, as shown in FIG. 3.

The pulse variable unit 310 can receive the input clock signal ‘in’ and the delay clock signal ‘D_in’ to generate the first and second clocks signals ‘clk1’ and ‘clk2’. The pulse variable unit 310 can include a first pulse generating unit 311 and a second pulse generating unit 312.

The first pulse generating unit 311 can receive the input clock signal ‘in’ and the delay clock signal ‘D_in’ to generate the first clock signal ‘clk1’. In certain embodiments, the first clock signal ‘clk1’ can be generated so that its high-level interval is shorter than the high-level interval of the input clock signal ‘in’.

The first pulse generating unit 311 can include a thirteenth NAND gate ND21 and a first inverter IV21. The thirteenth NAND gate ND21 can receive the input clock signal ‘in’ and the delay clock signal ‘D_in’. The first inverter IV21 can receive an output signal from the thirteenth NAND gate ND21 to output the first clock signal ‘clk1’.

The second pulse generating unit 312 can receive the input clock signal ‘in’ and the delay clock signal ‘D_in’ to generate the second clock signal ‘clk2’. In certain embodiments, the second clock signal ‘clk2’ can be generated so that its high-level interval is greater than the high-level interval of the input clock signal ‘in’.

The second pulse generating unit 312 can include a NOR gate NOR21 and a second inverter IV22. The NOR gate NOR21 can receive the input clock signal ‘in’ and the delay clock signal ‘D_in’. The second inverter IV22 can receive an output signal from the NOR gate NOR21 to output the second clock signal ‘clk2’.

The selection output unit 320 can be configured to select one of the output signals from the pulse variable unit 310, i.e., one of the first clock signal ‘clk1’ and the second clock signal ‘clk2’, in response to the control signal ‘PS’ to output the output clock signal ‘OUT’.

The selection output unit 320 can be configured, as shown in FIG. 3, as a multiplexer or pass gate, which selects one of multiple input signals, i.e., first and second clock signals ‘clk1’ and ‘clk2’, and outputs it as an output clock signal ‘OUT’.

The selection output unit 320 can output the first clock signal ‘clk1’ when the control signal ‘PS’ is enabled, and the second clock signal ‘clk2’ when the control signal ‘PS’ is disabled.

The selection output unit 320 can include a third inverter IV23, and fourteenth to sixteenth NAND gates ND22 to ND24. The third inverter IV23 can receive the control signal ‘PS’. The fourteenth NAND gate ND22 can receive an output signal from the first inverter IV21 and the first clock signal ‘clk1’. The fifteenth NAND gate ND23 can receive the control signal ‘PS’ and the second clock signal ‘clk2’. The sixteenth NAND gate ND24 can receive an output signal from the thirteenth NAND gate ND22 and an output signal from the fifteenth NAND gate ND23 to output the output clock signal ‘OUT’.

Each or any of the whole NAND gates ND21 to ND24 and the NOR gate NOR21 that constitute the pulse width modulating unit 300 can be implemented as a symmetrical structure.

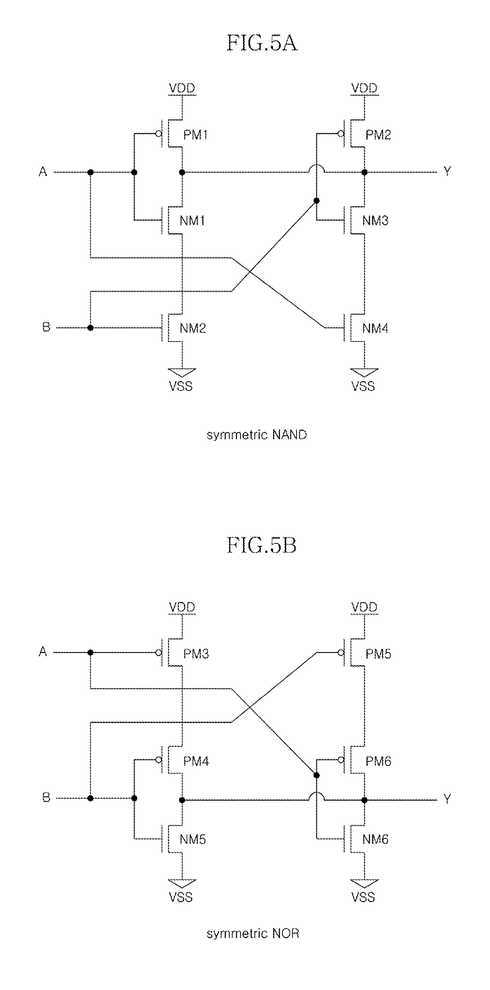

The NAND gate shown in FIG. 5A is an example of a symmetric NAND gate. In such a symmetrical NAND gate, the NAND gate includes first and second PMOS transistors PM1 and PM2, and first to fourth NMOS transistors NM1 to NM4. The first PMOS transistor PM1, the first NMOS transistor NM1, and the second NMOS transistor NM2 can be connected in series between an external voltage terminal VDD and a ground terminal VSS. The second PMOS transistor PM2, the third NMOS transistor NM3, and the fourth NMOS transistor NM4 can be connected in series between an external voltage terminal VDD and a ground terminal VSS. The first PMOS transistor PM1, the first NMOS transistor NM1, and the fourth NMOS transistor NM4 receive a first input signal ‘A’ through their respective gate terminals. The second PMOS transistor PM2, the second NMOS transistor NM2, and the third NMOS transistor NM3 receive a second input signal ‘B’ through their respective gate terminals. An output signal ‘Y’ of the NAND gates is outputted from a common node to which the drain terminal of the first PMOS transistor PM1 and the drain terminal of the second PMOS transistor PM2 are connected.

An operation of such a symmetric NAND gate will be described below.

First, like a general NAND gate, when the first input signal ‘A’ and the second input signal ‘B’ are both at a high level, the output signal ‘Y’ is at a low level, otherwise, the output signal ‘Y’ is at a high level. The general NAND gate and the symmetric NAND gate both output the same output signal under the same input condition. However, in the symmetric NAND gate, nodes that determine the level of the output signal ‘Y’ by the first input signal ‘A’ and the second input signal ‘B’ are equal to each other in length. Accordingly, in the symmetric NAND gate, a time required to generate a high level or a low level of an output signal ‘Y’ by the first input signal ‘A’ is substantially equal to a time required to generate a high level or a low level of an output signal ‘Y’ by the second input signal ‘B’.

The NOR gate shown in FIG. 5B is an example of a symmetric NOR gate. Such a symmetric NOR gate includes third to sixth PMOS transistors PM3 to PM6, and fifth and sixth NMOS transistors NM5 and NM6. The third PMOS transistor PM3, the fourth PMOS transistor PM4, and the fifth NMOS transistor NM5 are connected in series between an external voltage terminal VDD and a ground terminal VSS. The fifth PMOS transistor PM5, the sixth PMOS transistor PM6, and the sixth NMOS transistor NM6 are connected in series between an external voltage terminal VDD and a ground terminal VSS. The third PMOS transistor PM3, the sixth PMOS transistor PM6, and the sixth NMOS transistor NM6 receives a first input signal ‘A’ through their respective gate terminals. The fourth PMOS transistor PM4, the fifth PMOS transistor PM5, and the fifth NMOS transistor NM5 receive a second input signal ‘B’ through their respective gate terminals. An output signal ‘Y’ is outputted from a common node to which the drain terminal of the fifth NMOS transistor NM5 and the drain of the sixth NMOS transistor NM6 are connected. When the first input signal ‘A’ and the second input signal ‘B’ are both at a low level, the output signal ‘Y’ is at a high level.

The symmetric NOR gate shown in FIG. 5B has the same advantages as those of the symmetric NAND gate described above with regard to FIG. 5A. The NOR gate outputs the output signal ‘Y’ after the same delay time irrespective to the first input signal ‘A’ and the second input signal ‘B’. Thus, in certain embodiments, symmetric NOR gates can also be used

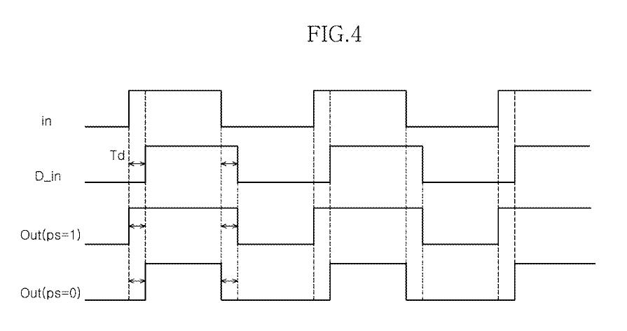

An operation of the duty cycle correcting circuit 101 will now be described with reference to FIG. 4.

The delay clock signal ‘D_in’ is a signal which has been delayed by the delay time (Td) compared to the input clock signal ‘in’.

If the input clock signal ‘in’ and the delay clock signal ‘D_in’ are both at a high level, then the first clock signal ‘clk1’ is generated at a high level. That is, the input clock signal ‘in’ and the delay clock signal ‘D_in’ are logically ANDed to generate the first clock signal ‘clk1’.

Further, if any of the input clock signal ‘in’ and the delay clock signal ‘D_in’ is at a high level, then the second clock signal ‘clk2’ is generated at a high level. That is, the input clock signal ‘in’ and the delay clock signal ‘D_in’ are logically ORed to generate the second clock signal ‘clk2’.

In the example of FIG. 4, the high level interval of the first clock signal ‘clk1’ is less than the high level interval of the input clock signal ‘in’ by the delay time (Td), and the high level interval of the second clock signal ‘clk2’ is greater than the high level interval of the input clock signal ‘in’ by the delay time (Td).

If the control signal ‘PS’ is disabled, e.g., at a high level, then the first clock signal ‘clk1’ is output as the output clock signal ‘OUT’. If the control signal ‘PS’ is enabled, e.g., at a low level, then the second clock signal ‘clk2’ is output as the output clock signal ‘OUT’. And, as the delay time (Td) lengthens, the high-level interval of the first clock signal ‘clk1’ increases and the high-level interval of the second clock signal ‘clk2’ decreases.

The duty cycle correcting circuit 101 can thus control the high-level interval of the output clock signal ‘OUT’ by performing a digital level logical operation on the input clock signal ‘in’ and the delay clock signal ‘D_in’. Accordingly, the exemplary embodiment described herein can perform a duty ratio correcting operation of a clock despite reducing the length of the delay line, i.e., variable delay unit. Furthermore, the total number of inverters used in the embodiments described herein is reduced, thereby reducing power consumption even though the frequency of the clock signal increases. Moreover, the reduced number of inverters effectively reduces the jitter of the circuit.

While certain embodiments have been described above, it will be understood that the embodiments described are by way of example only. Accordingly, the circuit device and method described herein should not be limited based on the described embodiments. Rather, the devices and methods described herein should only be limited in light of the claims that follow when taken in conjunction with the above description and accompanying drawings.

What is claimed is:

1. A duty cycle correcting circuit, comprising:
a duty detector that detects a duty ratio of an output clock signal to output a duty detection signal;
a variable delay unit that outputs a delay clock signal obtained by variably delaying a input signal according to the duty detection signal; and
a pulse width modulating unit that generates a first clock signal that is at a high level when both the input clock signal and the delay clock signal are at a high level and generates a second clock signal that is at a high level when any of the input clock signal and the delay clock signal is at a high level,
wherein the pulse width modulating unit selectively outputs the first clock signal or the second clock signal as the output clock signal.

2. The duty cycle correcting circuit of claim 1, wherein the variable delay unit increases a delay time by which the input signal is delayed if the duty detection signal is enabled, and decreases the delay time if the duty detection signal is disabled.

3. The duty cycle correcting circuit of claim 2, wherein the variable delay unit includes:
a coarse delay line that increases or decreases the delay time according to a coarse control signal;
a fine delay line that increases or decreases the delay time according to a fine control signal;
a counting unit that up-counts or down-counts a counter value in response to the duty detection signal; and
a decoder that decodes the counter value to generate the coarse control signal and the fine control signal,
wherein the counting unit outputs the most significant bit of the counter value as a control signal.

4. The duty cycle correcting circuit of claim 3, wherein the pulse width modulating unit includes:
a pulse variable unit that receives the input clock signal and the delay clock signal to output a plurality of output signals which are different in pulse width from each other, and
a selection output unit that selects one of the plurality of output signals in response to the control signal and outputs the selected output signal as the output clock signal.

5. The duty cycle correcting circuit of claim 4, wherein the pulse variable unit includes:
a first pulse generating unit that receives the input clock signal and the delay clock signal to output a first clock signal whose high-level interval is increased compared to the high-level interval of the input clock signal, and
a second pulse generating unit that receives the input clock signal and the delay clock signal to output a second clock signal whose high-level interval is decreased compared to the high-level of the interval of the input clock signal.

6. The duty cycle correcting circuit of claim 5, wherein the first pulse generating unit is configured to output the first clock signal that is at a high level if the input clock signal and the delay clock signal are both at a high level.

7. The duty cycle correcting circuit of claim 5, wherein the second pulse generating unit is configured to output the second clock signal that is at a high level if any of the input clock signal and the delay clock signal is at a high level.

8. The duty cycle correcting circuit of claim 6, wherein the first pulse generating unit includes a symmetric NAND gate.

9. The duty cycle correcting circuit of claim 7, wherein the second pulse generating unit includes a symmetric NOR gate.

10. A method for correcting a duty cycle, comprising:
detecting a duty ratio of an output clock signal to output a duty detection signal;
outputting a delay clock signal that is obtained by variably delaying a input signal according to the duty detection signal; and
correcting the duty ratio of the output clock signal by increasing or decreasing a width of a high-level pulse of the output clock signal as much as a delay time by which the delay clock signal is delayed according to the duty ratio of the output clock signal.

11. The duty cycle correcting method of claim 10, wherein the correcting of the duty ratio includes:
ANDing the input signal and the delay clock signal to generate a first clock signal,
ORing the input signal and the delay clock signal to generate a second clock signal, and
outputting one of the first clock signal and the second clock signal as the output clock signal.

12. A duty cycle correcting circuit, comprising:
a duty detector that outputs a duty detection signal based upon a duty ratio of an output clock signal;
a variable delay unit that outputs a delay clock signal based upon the duty detection signal and a input clock signal, and outputs a control signal based upon the duty detection signal;
a first pulse generating unit that outputs a first clock signal based upon the delay clock signal;
a second pulse generating unit that outputs a second clock signal based upon the delay clock signal; and
a selection output unit that outputs the output clock signal based upon the first clock signal, the second clock signal, and the control signal.

13. The duty cycle correcting circuit of claim 12, wherein the variable delay unit includes a delay control unit, a course delay line, and a fine delay line.

14. The duty cycle correcting circuit of claim 13, wherein the delay control unit includes a counting unit that increases or decreases counter values based upon detection of the duty detection signal.

15. The duty cycle correcting circuit of claim 14, wherein a most significant bit of the counter values is output as the control signal.

16. The duty cycle correcting circuit of claim 13, wherein the delay control unit outputs a plurality of course control signals to the course delay line to generate one of a minimum, intermediate, and maximum course time delay of the input clock signal.

17. The duty cycle correcting circuit of claim 16, wherein the delay control unit outputs a plurality of fine control signals to the fine delay line to adjust a phase of the course time delayed input clock signal.

18. The duty cycle correcting circuit of claim 17, wherein the fine delay line includes a delay unit that delays the course time delayed input clock signal.

19. The duty cycle correcting circuit of claim 18, wherein the fine delay line includes a phase mixer that is controlled by the plurality of fine control signals to output the delay clock signal having a phase between the phase of the course time delayed input clock signal and the delayed course time delayed input clock signal.
